(19) United States
(12) Patent Application Publication
(10) Pub. No.: US 2012/0184086 A1
(43) Pub. Date: Jul. 19, 2012

(54) PUNCH SINGULATION SYSTEM AND METHOD

(76) Inventors: Hae Choon Yang, Singapore (SG); Xue Fang Shen, Singapore (SG); Deok Chun Jang, Singapore (SG); Chong Chen Lim, Singapore (SG); Siok Chun Lim, Singapore (SG); Yun Suk Shin, Singapore (SG)

(21) Appl. No.: 13/498,577

(22) PCT Filed: Sep. 24, 2010
(86) PCT No.: PCT/SG2010/000360

§ 371 Date: Mar. 27, 2012

(30) Foreign Application Priority Data
Sep. 28, 2009 (SG) 200906521-0

(51) Int. Cl. H01L 21/78; B26D 7/06; B26D 5/20

(52) U.S. Cl. 438/464; 83/401; 83/418; 257/E21.599

(57) ABSTRACT

A punching system for singulating IC units comprising: a punching assembly arranged to receive a substrate and singulate said substrate into the IC units; a rotary carrier rotatable from a first position to a second position said rotary carrier arranged to receive said units at the first position and carry said units to the second position through rotation; wherein said rotary carrier includes recesses for receiving at least a portion of the units. A punching assembly comprising a die block having recesses for receiving selectively replaceable inserts wherein said inserts correspond to a punch pattern specific to a predetermined IC package arrangement.

### FIELD OF THE INVENTION

The invention relates to the singulation of integrated circuit units (ICU's) from a substrate containing a plurality of said units. In particular, the singulation method according to the present invention relates to a stamping or punching process and may be suited particularly for QFN (Quad Flat No-lead) units.

### BACKGROUND

Substrates containing integrated circuit units require singulation before delivery to the end user. The means of singulating the units from the substrate include sawing, water jets, laser and punching. Which method of singulation used will depend upon the required speed of processing, the nature of the substrate and the nature of the individual units. For QFN units for instance, punching the units from a substrate is a common technique favoured for the speed of processing and suited as the plastic molding often used on other unit types is not required for QFN.

### SUMMARY OF INVENTION

In a first aspect, the invention provides a method for singulating IC units comprising the steps of: delivering a substrate to a punching assembly; singulating said substrate into the IC units; providing a rotary carrier having recesses for receiving at least a portion of the units; receiving said units at the first position on a rotary carrier; carrying said units to a second position through rotating the rotary carrier from the first position to the second position.

In a second aspect, the invention provides a punching system for singulating IC units comprising: a punching assembly arranged to receive a substrate and singulate said substrate into the IC units; a rotary carrier rotatable from a first position to a second position said rotary carrier arranged to receive said units at the first position and carry said units to the second position through rotation; wherein said rotary carrier includes recesses for receiving at least a portion of the units.

Accordingly, the punching system incorporating the rotary carrier provides a number of advantages. For instance, having a plurality of recesses allows a buffer of units to be transferred from the punching assembly to down stream processes. Further it allows flexibility on whether the process is linear should the rotary carrier received the units in direct line with the punching assembly or more compact if it receives the unit at right angles suited the punching assembly.

In a further embodiment, the punching assembly may be a two-stage process whereby a substrate undergoes a punching stage along each edge of a first axis followed by a second stage punching each edge along the orthogonal axis. The punching assembly may have a press and a cam shaft mounted thereto such that each stage is synchronized.

Further the rotation of the rotary carrier may also be synchronized with one or both of the punching stages. To this end, the rotary carrier may be in communication with the cam shaft to achieve this synchronization.

In this embodiment, for the processing of substrates, a substrate may enter the first axis punch (for instance x-axis) followed by the orthogonal axis (such as a y-axis) punch and then have the singulated units delivered to the rotary carrier. The timing of the rotary carrier to present a vacant recess to receive the singulated units maybe be synchronized with the punching stroke for the x and y-axis.

The punching system may further include a loading station. In one embodiment the loading station may have a stack loader having a stack of substrates. In this case, the upper most substrate on the stack loader may be lifted to an inlet rail and subsequently have the substrate delivered to the first stage punch.

Between the stack loader and the inlet rail may be located a flipper for receiving the substrate and flipping the substrate about a horizontal axis so as to have the substrate with the pad on the upper surface.

In a further embodiment, the punching system may include a sorting station capable of delivering the singulated IC units from the rotary carrier to respective bins based upon predetermined criteria. Said predetermined criteria may be received from a variety of inspection points.

A first inspection point may be located adjacent the index feeder so as to check the type of substrate and its orientation to ensure against misalignment.

A second station may be located above the rotary carrier and may be used to check a top surface of the IC unit, being the lead side, of each singulated unit whilst within the rotary carrier.

A third inspection point may be located between the rotary carrier and a shuttle and position beneath the delivery device taking the singulated units from the rotary carrier to the shuttle. Such a third inspection may be to confirm marking and fiduciary marks to check the bottom surface of the IC unit.

Thus providing a punch assembly whereby the die block includes selectively replaceable inserts may permits an effective means of reconfiguring the punching assembly to accommodate a different package size.

In one embodiment the predetermined IC package arrangement may be a 3×3, 4×4 etc.

Thus by providing inserts to accommodate different package sizes and different substrate sizes, there may be a substantial capital cost saving compared to replacing a full die when a substrate size is changed not to mention the downtime required for such a substantial change and thus the economic loss of taking the punching assembly offline.

### BRIEF DESCRIPTION OF DRAWINGS

It will be convenient to further describe the present invention with respect to the accompanying drawings that illustrate possible arrangements of the invention. Other arrangements of the invention are possible and consequently the particularity of the accompanying drawings is not to be understood as superceding the generality of the preceding description of the invention.

FIG. 1 is a plan view of a punching system according to one embodiment of the present invention;

FIGS. 2A and 2B are elevation views of a loading station according to one embodiment of the present invention;

FIG. 3 is an exploded isometric view of a punching die block according to one embodiment of the present invention; and

FIGS. 4A and 4B are exploded isometric views of the X and Y punch and die arrangements of a die block according to one embodiment of the present invention.

FIG. 5 is an exploded isometric view of the punch and die according to a further embodiment of the present invention.

### DETAIL DESCRIPTION

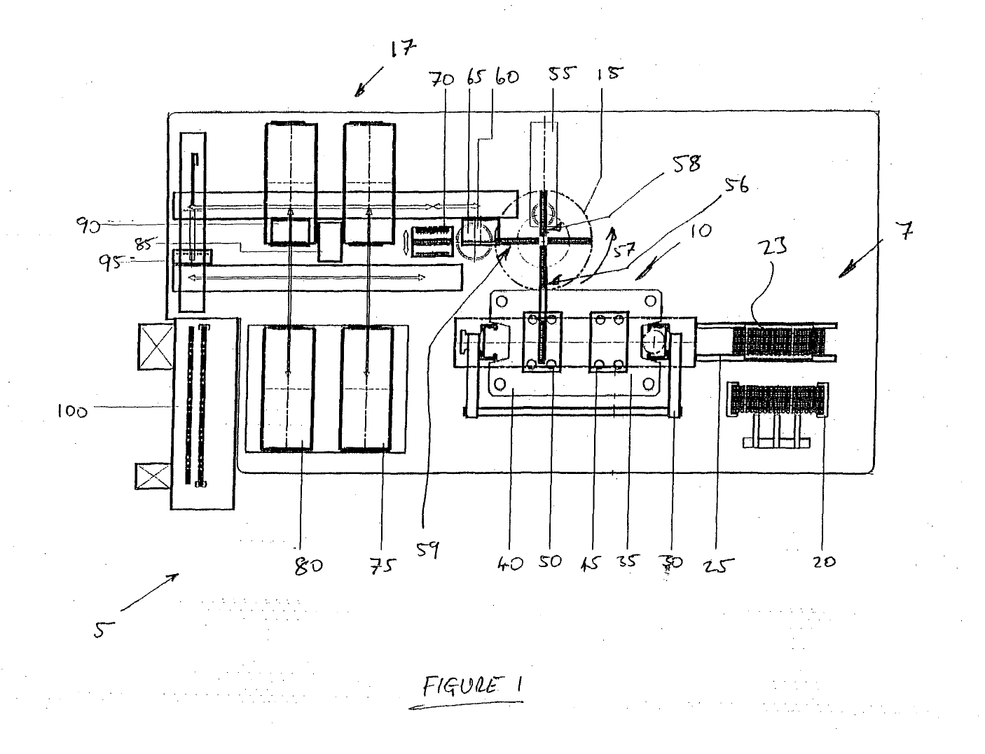

FIG. 1 shows a punching system 5 used for the singulation of IC units from a substrate. Punching is a preferred option for QFN packages and the arrangement shown in FIG. 1 is particularly suited to the processing of such QFN packages.

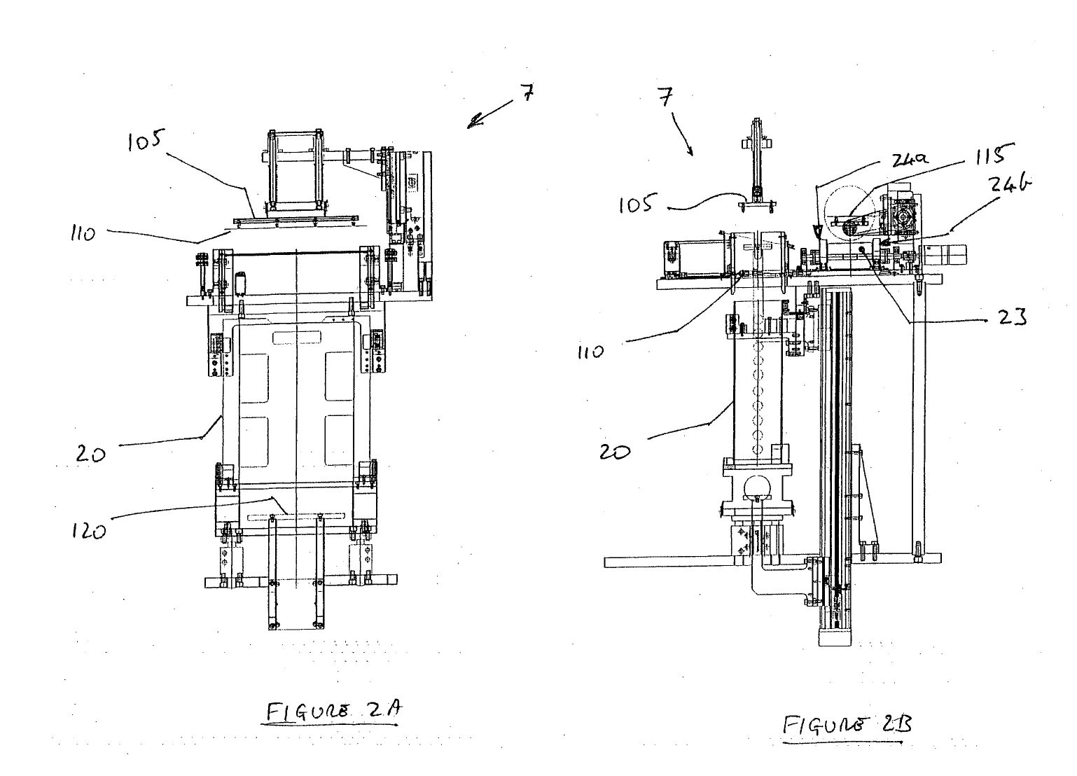

Substrates are loaded into a stack loader 20, such that the substrates are stacked one upon the other. FIGS. 2A and 2B show the loading station 7 including the stack loader 20. A lift 120 pushes the stack of substrate upwards so that an upper most substrate 110 can be engaged by a substrate picker 105.

The picker 105 lifts the substrate 110 and places it on a flipper 115 which flips the substrate and drops it onto an inlet rail 23. The flipper 115 has a vacuum engagement arrangement to hold the substrate in place with the substrate being released through release of the vacuum. The small drop from the flipper 115 to the inlet rail 23 is sufficiently low so as to avoid damage. The inlet rail 23 further includes guides 24a, b which provide a sufficiently close tolerance for the substrate so as to insure the substrate is oriented correctly.

The inlet rail 23 delivers the substrate to a first inspection point which includes a camera located on the index feeder. The purpose of the first inspection is to ensure the substrate is correctly oriented and to also identify the type of substrate in terms of size and unit type.

The substrate is then engaged by an index-feeding device 30 which engages the substrate and permits movement through the various stages of punching.

The punching assembly 10 involves a press operating on two punching blocks 45, 50, the two blocks acting to firstly punch in the x direction of the substrate and the second cut in the y direction.

It will be appreciated that the invention is not limited to the order in which the substrate is punched. Thus whilst in this embodiment the X punch is then followed by the Y punch, in fact the Y punch may precede the X punch. The particular order is immaterial to the invention, and how the units are then subsequently delivered downstream.

Further still, whilst in this embodiment a single line of units correspond to a single line of punches, in fact as shown in FIG. 5, more than one line of punches may be incorporated within the punching assembly. Further, whilst FIG. 5 shows a punching block capable of punching a second line of units, in fact, multiple lines can be punched subject to the number of lines of punches which are incorporated into the punching block.

The press is connected to the blocks through a cam shaft which permits the punching to be synchronized between the two blocks and so permitting a “punch-move-punch” sequence between the index-feeding and the press.

Punching the substrate along the y-axis separates the units from the substrates forming a plurality of singulated IC units. From the y-axis punch the units are transported to a rotary carrier 15. The rotary carrier 15 includes a plurality of recesses 56 into which the IC units may be placed. In this embodiment, the rotary carrier 15 includes four recesses which rotates 57 in a counter-clockwise direction in four stages to correspond to the four recesses. FIG. 1 shows one recess 56 adjacent to the y-axis punch ready to receive, in this case, a line of singulated units which are then transported by a line picker (not shown). The line picker engages one line of units from the substrate and places them in the recess. On placement, the rotary carrier rotates until the next recess is adjacent to the y-punch.

Synchronization of the x-punch 45, y-punch 50 and rotary carrier 15 is achieved through connection of those stations to a cam shaft such that each of the three devices perform the relevant action simultaneously. That is the x-punch 45 and y-punch 50 punch through the substrate with the rotary carrier rotating from recess to recess at the same time.

A particular advantage of the rotary carrier 15 is the ability to align one of said recesses with a camera 55 so as to create an inspection point. In this embodiment, the inspection point is arranged to inspect the pad of the QFN units which at this point are directed upwards. This information can then be transmitted further downstream so as to characterize the units according to quality.

Whilst the rotary carrier 15 is effective for transportation of the units to the slotting station, it also provides for a further inspection point without having to make special arrangement for the units in order to undergo the required inspection. A further embodiment, a second inspection point may also be incorporated should further information be required for the characterization of the units.

The rotary carrier 15 on its next rotation positions a recess 59 adjacent to the sorting station 17. Here a further line picker (not shown) delivers the plurality of IC units to a shuttle 70. The IC units pass over a third inspection station 65 which inspects the underside of the unit and in particular for marking, fiduciary marks and any other faults.

The third inspection station may also include a 2.5D inspection. Such an inspection station includes an array of mirrors arranged to encircle the IC units, through lowering the units into a space defined by the array. The provision of the mirrors allows the camera to have a view horizontally to check leads or vertical alignment of the units. It also allows a check of the side quality of the units that is to identify any faults along the side such as short circuits through a bleed through of material. Accordingly, with the direct bottom view, and 4 side views from four encircling mirrors, 5 separate views of the units are possible.

Once in the shuttle 70 unit pickers 90, 95 engage the units on the shuttle 70 for delivery to individual bins 75, 80, 85.

Based on the information received from the three inspection stations 35, 55, 65 the units are deposited in the “good”, “rework” or “reject” bins.

As an alternative to placement in the “good bin”, a tube off loader 100 is also provided, subjected to the preference of the end user.

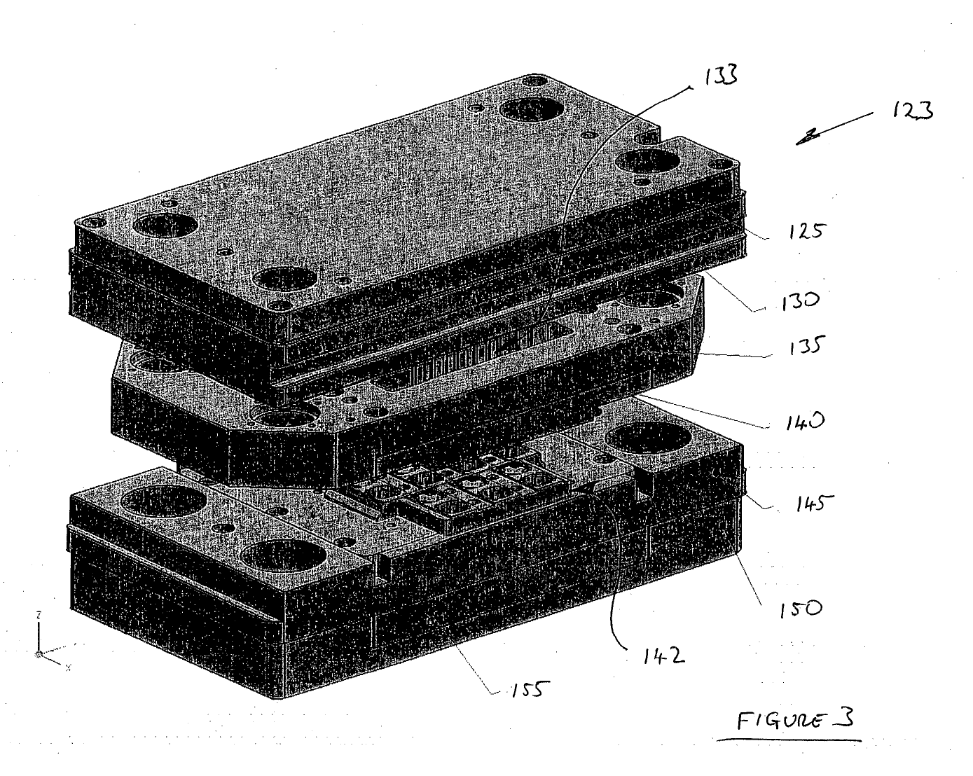

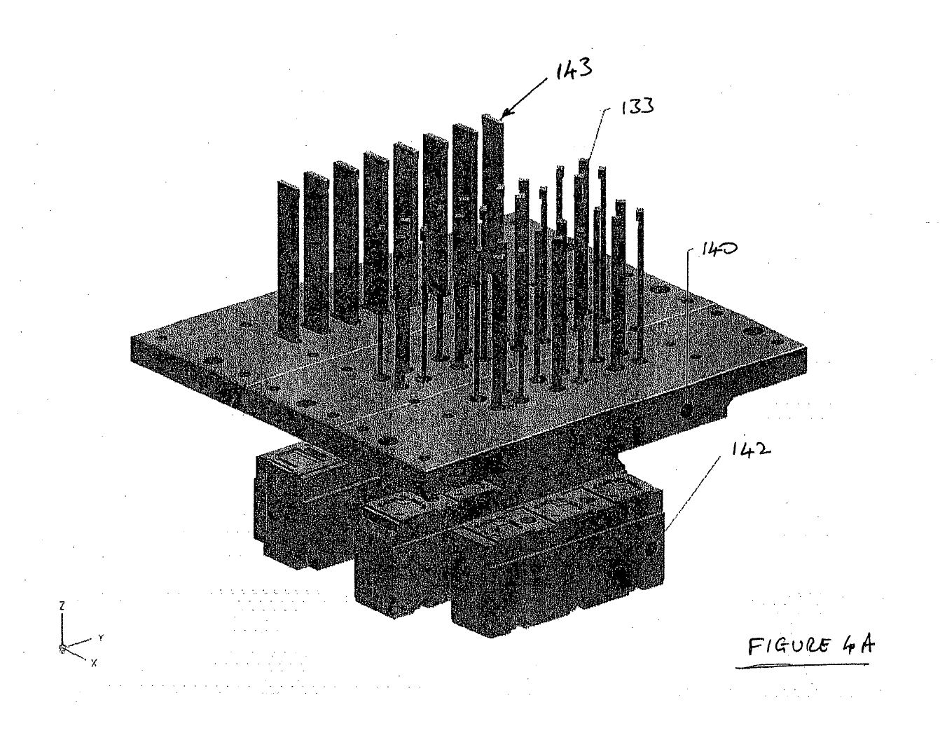

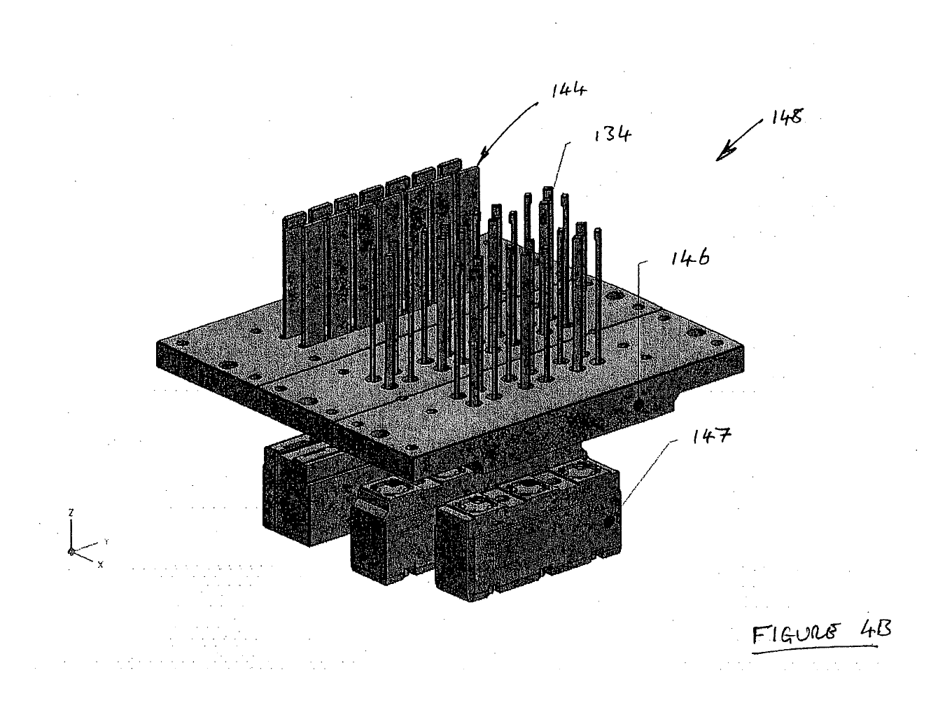

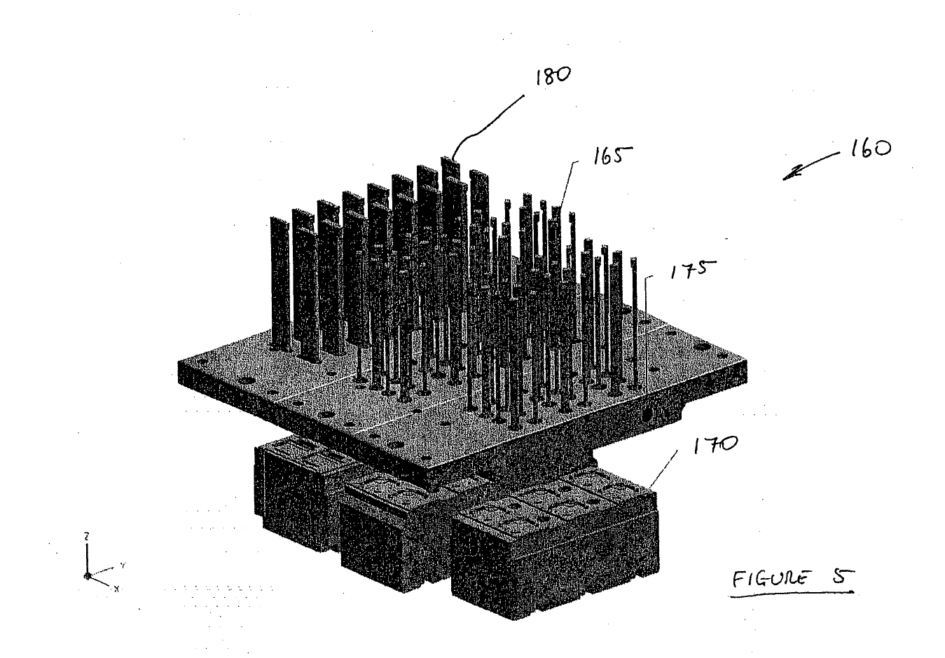

FIGS. 3, 4A show a die block assembly 123 for a Y cut, with FIG. 4B showing the corresponding X cut. These are used for the punching of a substrate the singulation of IC units from the substrate. As mentioned previously punching is a process well suited to QFN packages.

The die assembly includes a punch back plate 125 mounted on a punch holder and retainer 130. This coupled to a stripper holder 135 all of which encompass the punches 133.

The punches are arranged to pass through a stripper 140 which provides guidance and control for the full stroke of the punch as it impinges on a die 142 mounted within a die holder 145 and die back plate 150. To control and support the die 142 is a die plate insert 55.

A feature of this invention is the use of the die inserts 142 which are adapted to be placed within the die holder and die back plate. With the prior art relying upon a fixed arrangement for the die integral with the die holder, die back plate. In this case, the whole assembly must be replaced when the type of substrate is changed to accommodate the package. According to the present invention the use of die inserts 142 permits the insert to be swapped around according to the type of package being singulated. Accordingly the cost of a die block assembly 123 compared to that of the prior art is considerably cheaper when accommodating several different substrate sizes which may be applicable. The capital cost of having to replace the die holder and die back plate for changing over to a different substrate size is considerable. Further the amount of time required to change the die holder and back plate compared to that of merely the inserts is also considerably greater leading to less downtime for the entire punching process.

As previously discussed, multiple rows of units may be singulated subject to the number of punching sets incorporated within the block. Similarly, FIG. 4B shows the corresponding X cut die block 148, having punches 134, 144 and die inserts 147.

FIG. 5 shows a multiple row block 160 having multiple rows 180 of punches. It will be appreciated that three, four or more rows may also be used subject to the requirements of the end user, all of which fall within the present invention. Here, punches 165, 180 fit within strippers to accommodate multiple rows so as to align with the die inserts 170. A particular advantage of a multiple row punching assembly incorporating also the further aspect of the present invention which uses die inserts allows for multiple row punching assemblies to be configured according to the particular batch. Thus rather than having a full set of dies to accommodate a single row and a further set to accommodate multiple rows, the die inserts may be used and switched according to a particular application, thus die inserts for a single row may be swapped out and replaced with multiple rows as required.

1. A punching system for singulating IC units comprising:
a punching assembly arranged to receive: a substrate and singulate said substrate into the IC units;
a rotary carrier rotatable from a first position to a second position said rotary carrier arranged to receive said units at the first position and carry said units to the second position through rotation;
wherein said rotary carrier includes recesses for receiving at least a portion of the units.

2. The punching system according to claim 1, wherein the punching assembly includes two blocks such that a first block punches the substrate along one axis and the second block punches along an orthogonal axis.

3. The system according to claim 2 further including a cam shaft mounted to a press said first and second blocks in communication with said cam shaft so as to permit simultaneous operation of the two punch blocks.

4. The system according to any one of the preceding claims wherein rotation of the rotary carrier is in synchronized communication with the first and second blocks.

5. The system according to claim 4 wherein the synchronized communication of the rotary carrier and the first and second blocks is provided by the cam shaft.

6. The punching system according to any one of the preceding claims further including a loading station for loading a substrate to the punching assembly said loading station including a stack loader arranged to stack a plurality of said substrates for delivery sequentially to the punching assembly.

7. The punching system according to claim 6 further including a flipper such that a substrate delivered from the stack loader to the punching assembly is placed upon a flipper and flipped prior to placement on an inlet rail directed to the punching assembly.

8. The punching system according to any one of the preceding claims wherein the punching assembly includes multiple rows of punches so as to simultaneously punch multiple rows of IC units.

9. A punching assembly comprising:
a die block having recesses for receiving selectively replaceable inserts;
wherein said inserts correspond to a punch pattern specific to a predetermined IC package arrangement.

10. The punching assembly according to claim 9, wherein said predetermined IC package arrangement includes a QFN arrangement.

11. The punching assembly according to claim 10, wherein said QFN arrangement includes a 3×3, 4×4 or 5×5 arrangement.

12. A method for singulating IC units comprising the steps of:
delivering a substrate to a punching assembly;
singulating said substrate into the IC units;
providing a rotary carrier having recesses for receiving at least a portion of the units;
receiving said units at the first position on a rotary carrier;
carrying said units to a second position through rotating the rotary carrier from the first position to the second position.
